(19) United States
(12) Patent Application Publication
(10) Pub. No.: US 2003/0164721 A1
(43) Pub. Date: Sep. 4, 2003

(54) GATE DRIVE CIRCUITRY

(76) Inventor: Jeffrey A. Reichard, Oconomowoc, WI (US)

Correspondence Address: FISH & RICHARDSON PC, 225 FRANKLIN ST, BOSTON, MA, 02110, US

(21) Appl. No.: 10/086,332

(22) Filed: Mar. 1, 2002

(51) Int. Cl. H03B 1/00

(52) U.S. Cl. 327/108

(57) ABSTRACT

Circuitry includes control logic circuitry, switching circuitry, and a signal transmission path. The control logic circuitry is adapted to provide a first control signal for controlling switching characteristic of and for supplying power to the switching circuitry. The switching circuitry has an input for receiving the first control signal and an output for providing a second control signal to the power semiconductor device. The signal transmission path is configured to carry the first control signal from the control logic circuitry to the input of the switching circuitry and power for the switching circuitry.

### BACKGROUND

The invention relates to driver circuitry for controlling semiconductor devices, for example, those used in switching circuitry.

Power semiconductor devices, such as the insulated gate bipolar transistor (IGBT), a type of high-speed, high-power switch are incorporated with other passive electronic components (resistors, capacitors, inductors) into power electronic converter modules. IGBT's typically operate in the 300 to 6000 volt range and at switching frequencies up to 20 KHz.

These power converters are used commercially today in power quality and reliability products and typically incorporate switching circuitry. In operation, the switching circuitry receives a DC voltage and is controlled to generate a pulse width modulated (PWM) signal. This power signal is then provided to a filter network to provide an AC power signal. Typically, the DC signal is pulsed and applied to the primary windings of a transformer. This, in turn, generates a pulsed signal on the secondary windings of the transformer, where the amplitude of the secondary signal is varied in accordance with the ratio of primary to secondary transformer windings. A rectifier and capacitor are typically employed to smooth the pulsed secondary voltage into an AC voltage. Controlling the switching circuitry is typically accomplished using gate driver circuitry.

Referring to FIG. 1, conventional gate driver circuitry 1 includes control logic 2 for providing control signals to a driver circuit 3. An optocoupler 4 is connected between control logic 2 and driver circuit 3 to provide electrical isolation between the two. Driver circuit 2 is connected to the gate and emitter of the high-power switching component, here an IGBT 5, through an output stage 6. Each of the optocoupler 4, driver circuit 2, and output stage 6 require a supply voltage to operate. The necessary supply voltage is provided by a power supply 7, which is electrically coupled to a driver circuit 8 through a transformer 9. Driver circuit 8 receives at its input, signals from oscillator circuitry 10 and generates the necessary control signals for switching field effect transistors (FETs) 12a, 12b. FETs 12a, 12b are connected in a “push-pull” topology and serve as the primary-side switches. Power supply 7 is connected to the secondary winding of transformer 9. It is important to note that optocoupler 4 and transformer 9 both independently serve to provide isolation between that part of gate driver circuitry 1 operating at logic potential and that part of gate driver circuitry operating at power potential (a dashed line in FIG. 1 shows the isolation path). Isolation is necessary to protect the logic control portion of the circuitry from the much higher voltage portion (>1,000 v) of the circuit.

### SUMMARY

The invention relates to a gate driver circuitry for controlling power semiconductor devices.

In a general aspect of the invention, the circuitry includes control logic circuitry, switching circuitry, and a signal transmission path. The control logic circuitry is adapted to provide a first control signal for controlling switching characteristics of and for supplying power to the switching circuitry. The switching circuitry has an input for receiving the first control signal and an output for providing a second control signal to the power semiconductor device. The signal transmission path is configured to carry the first control signal from the control logic circuitry to the input of the switching circuitry as well as the power for the switching circuitry.

Embodiments of this aspect of the invention may include one or more of the following features.

The signal transmission path includes an isolation device (e.g., a transformer) electrically connected between the switching circuitry and the control logic circuitry. For example, the transformer allows PWM signals generated by the control logic circuitry to be coupled to the switching circuitry while also isolating the control logic circuitry from the switching circuitry.

The signal transmission path includes a DC blocking element between the control logic circuitry and the isolation device. The control logic circuitry includes a driver circuit for driving an N-channel FET and a P-channel FET for generating the first control signal. The first control signal is a pulse-width modulated (PWM) signal. The second control signal is a DC-modified signal that increases in response to an increase of pulse width of the PWM signal.

The switching circuitry is configured to receive an alternating current signal and generate a direct-current second control signal. The switching circuitry is configured to provide synchronous rectification. The switching circuitry is configured to increase the power flowing through the power semiconductor device by increasing the pulse width of the PWM signal. The power semiconductor device is an insulated gate bipolar transistor. The switching circuitry is configured to operate at frequencies in a range between 10 KHz and 100 MHz (e.g., 10 MHz).

In another aspect of the invention, a method for controlling a power semiconductor device includes the following steps. A first control signal is generated using control logic circuitry. The first control signal is sent to a switching circuitry via a signal transmission path that provides electric isolation between the control logic circuitry and the switching circuitry. A second control signal is generated from the first control signal using the switching circuitry. Electric power is supplied from the first control signal in order to power the switching circuitry. The power semiconductor device is controlled using the second control signal.

In embodiments of this aspect of the invention, the control logic circuitry operates at logic potential and the switching circuitry operates at power potential.

Among other advantages, the signal transmission path provides control signals needed to switch the power semiconductor device, but also the power required to operate the switching circuitry. This eliminates the need to provide a separate path for providing power, thereby making the circuitry more robust, more cost efficient, and less susceptible to damage.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a block diagram, partially schematic, of conventional gate driver circuitry

FIG. 2A-B are block diagrams, partially schematic, of gate driver circuitry in accordance with the invention.

FIGS. 3A-3G are timeline diagrams of various signals measured at various points in the gate driver circuitry of FIG. 1 when the power transistor is turned on.

FIGS. 4A-4G are timeline diagrams of various signals measured at various points in the gate driver circuitry of FIG. 1 when the power transistor is turned off.

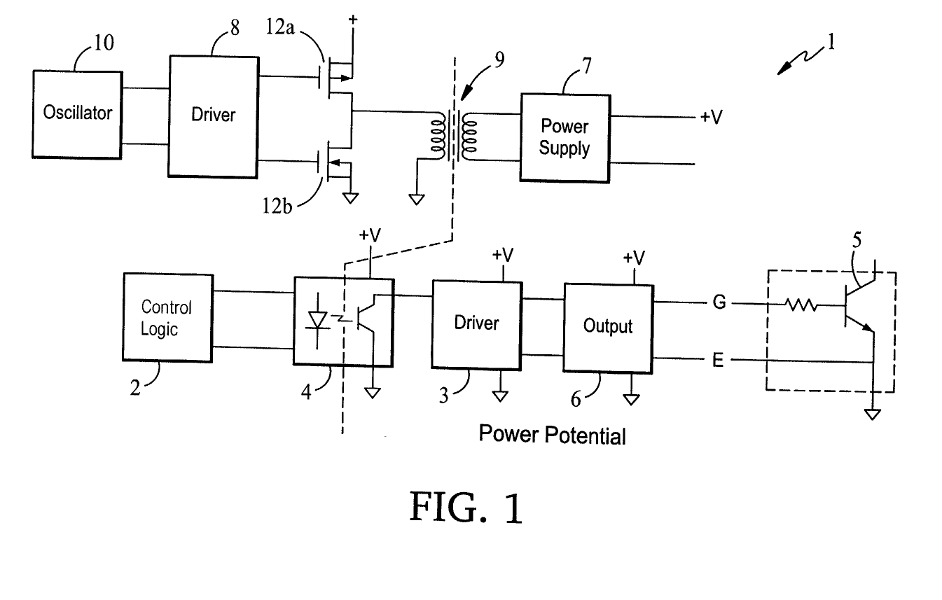

### DETAILED DESCRIPTION

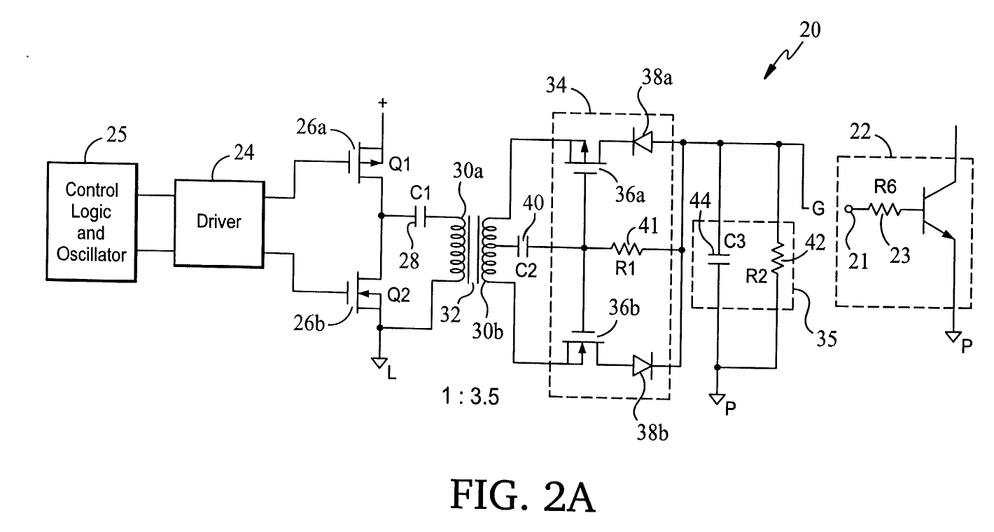

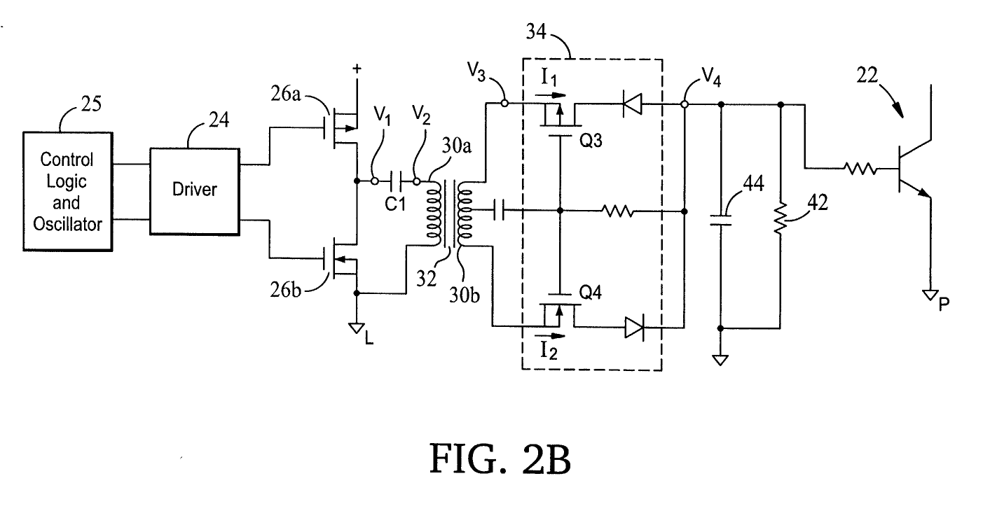

Referring to FIG. 2A, a gate driver circuit 20 for providing control signals to a gate terminal 21 of a high-power switching transistor, here an IGBT 22, is shown. Gate driver circuit 20 includes a control logic and oscillator circuit 25, the operation of which will be described in greater detail below, provides a control signal to a driver circuit 24 for providing the necessary drive signals to respective gates of field effect transistors (FETs) 26a, 26b. Control logic and oscillator circuit 25 can be implemented in a variety of hardware and software configurations. In one embodiment, the control logic and oscillator circuit 25 includes a microprocessor and programmable logic array (neither shown), which are configured and programmed to provide the appropriate control signals for generating pulse-width, modulated signals. The switched output of FETs 26a, 26b is passed through blocking capacitor 28 to remove the DC component before being received by a primary winding 30a of a transformer 32. A secondary winding 30b of transformer 32 provides a stepped-up voltage of the pulse-width modulated signal from primary winding 30a. A steering circuit 34 rectifies the pulse-width modulated signal, which is smoothed by an output filter 35 to provide a DC current signal which is provided to gate terminal 21 of IGBT 22 via a gate resistor 23. The component value for gate resistor 23 is selected on the basis of the particular IGBT that is being controlled.

Steering circuit 34 is a switching circuit and can be any of a wide variety of level-sensitive rectifier circuits (e.g., full bridge) or toggle circuits that operate in one polarity for a half-cycle, and reverse for the subsequent half. Steering circuit 34 is arranged to provide level-sensitive synchronous rectification. By level-sensitive rectification it is meant that if the rectangularly shaped pulse width modulated signal is above a predetermined threshold value (e.g., 3V), the polarity toggling preferably occurs at the point it crosses the threshold value. On the other hand, if the signal is below the threshold, switching does not occur.

In this embodiment, steering circuit 34 includes a pair of power MOSFET devices 36a, 36b, and corresponding pair of diodes 38a, 38b arranged in a bidirectional rectifier topology. More particularly, each of power MOSFET devices 36a, 36b when paired with a corresponding one of the diodes 38a, 38b provides a half-wave synchronous rectifier and together form the bi-directional rectifier. MOSFETs 36a, 36b are N-channel and P-channel MOSFETs, respectively, each having its gate terminal connected to the center tap of secondary winding 30b of transformer 32, via a capacitor 40. A resistor 41 is connected as well between the gates of MOSFETs 36a, 36b and the output of steering circuit 34. MOSFETs suitable for use in steering circuit 34 include dual logic level packaged devices, sold under the trademark HEXFET® and commercially available from International Rectifier, El Segundo, Calif. In this embodiment, output filter 35 is an RC filter including a shunt resistor 42 and bypass capacitor 44.

In one embodiment of gate driver circuit 20, the resistors and capacitors have the following component values:

| | | |
|---|---|---|
| Capacitor 40 (C2): | 0.01 | microfarads |
| Resistor 41 (R1): | 0.1 | ohms |
| Resistor 42 (R2): | 100 | ohms |
| Capacitor 44(C3): | 0.1 | microfarads |

Gate driver circuit 20 operates at relatively high frequencies, for example, 10 MHz. In other embodiments, the frequency of operation can extend between 10 KHz and 100 MHz. In operation, control logic and oscillator circuit 25 generates a PWM signal with positive peak voltage when IGBT 22 is desired to be turned on. The PWM signal controls driver 24, which in turn drives the gate of FET's Q1 26a and Q2 26b. A positive PWM signal turns on transistor Q1 26a during the positive pulse cycle while transistor FET 26b remains off. Current flowing from transistor FET 26a to primary winding 30a of transformer 32 results in a positive pulse signal being generated in secondary winding 30b. Steering circuit 34 rectifies the positive pulse signal, which is smoothed by output filter 35, resulting in a positive voltage generated at the base node of IGBT 22. By increasing the duty cycle of the PWM signal generated by control logic and oscillator circuit 25, the voltage at the base node of IGBT 22 is increased, thereby increasing the current flowing through IGBT 22.

When IGBT 22 is desired to be turned off, control logic and oscillator circuit 25 generates a PWM signal with negative peak voltage. A negative PWM signal turns on FET 26b during the negative pulse cycle while FET Q1 26a remains off. Current flowing from FET Q2 26b to primary winding 30a of transformer 32 results in a negative pulse signal being generated in secondary winding 30b of the transformer. Steering circuit 34 rectifies the negative pulse signal, which is smoothed by output filter 35, resulting in a negative voltage generated at the base node of IGBT 22. IGBT is thus turned off.

Referring to FIG. 2B, V1(t) is a PWM signal measured at the output of FETs Q1 26a and Q2 26b. The duty cycle of V1(t) is determined by control logic and oscillator circuit 25. V2(t) is a filtered PWM signal measured at the input of primary winding 30a. V2(t) is represents V1(t) without the direct current component. In this embodiment, V2(t) has a peak voltage of about 4.5 volts. V3(t) is measured at the output of secondary winding 30b. Transformer 32 has a ratio of about 1:3.5 between primary winding 30a and secondary winding 30b, thus V3(t) has a peak voltage of about 15.75 volts. V4(t) is the output of steering circuit 34. Because shunt resistor 42 and bypass capacitor 44 form a low pass filter, the alternating current component of V4(t) is filtered out, and V4(t) maintains a relatively constant voltage above zero. When V4(t) is above the threshold voltage value of IGBT 22, IGBT 22 is turned on. I1(t) is the current that flows through MOSFET Q3 36a, and I2(t) is the current that flows through MOSFET Q4 36b.

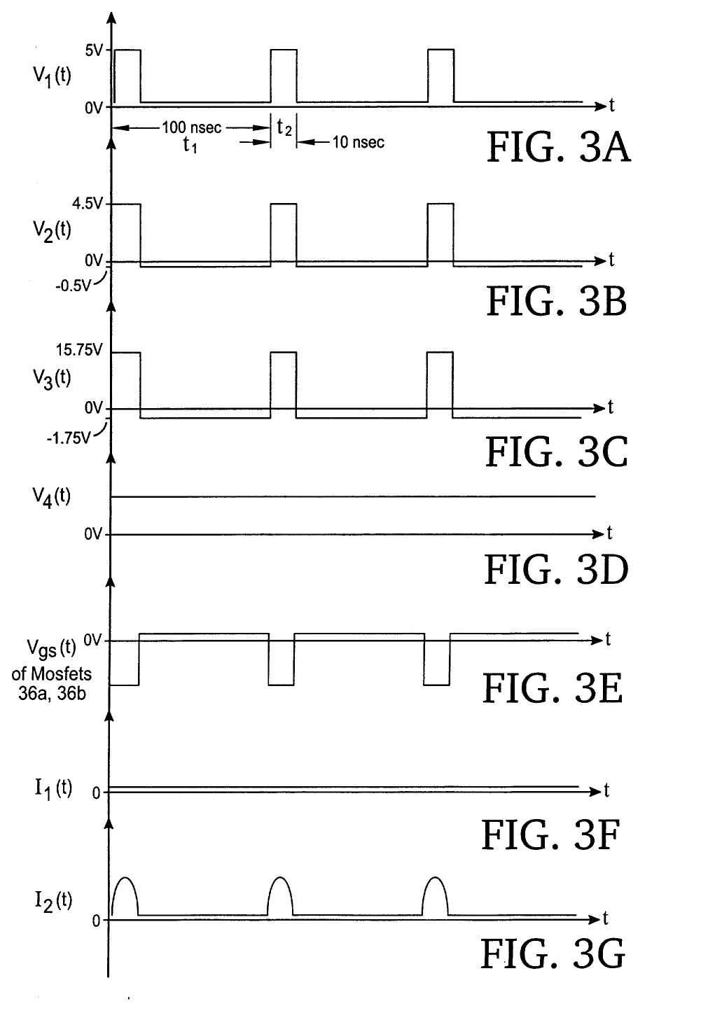

Referring to FIGS. 3A-3G, when IGBT 22 is desired to be turned on, control logic and oscillator circuit 25 generates signals to produce a positive pulse signal for V1(t). In this example, V1(t) is a positive pulse signal with a peak voltage of 5 volts and a period of 100 ns. The duty cycle of V1(t) is 10%, with a pulse width of 10 ns. Between time t=0 and t=t1, V1(t) is maintained at 5 volts, V2(t) is maintained at 4.5 volts, and V3(t) is maintained at 15.75 volts. Vgs(t) is the voltage difference between the gate and source nodes of MOSFETs 36a and 36b, and is maintained at a negative voltage during t=0 and t=t1. The exact value of this negative voltage is determined by the characteristics of the MOSFETs. Because MOSFET 36a is a negative-channel MOSFET, it is turned off when Vgs(t) is negative, and thus I1(t) is zero. Because MOSFET 36b is a P-channel MOSFET, it is turned on when Vgs(t) is negative, and thus I2(t) is positive during t=0 to t=t1. Current 12(t) flows through diode 38b and is shunted through resistor 35, creating a positive voltage drop V4(t) across the resistor.

Between time t=t1 and t=t2, V1(t) drops to zero, V2(t) drops to about −0.5 volts, and V3(t) drops to about −1.75 volts. Vgs(t) is maintained at a positive voltage but below the Vgs threshold voltage of MOSFET 36a. Therefore, MOSFET 36a remains off, and I1(t)=0. A positive Vgs(t) turns off the P-channel MOSFET 36b, thus I2(t)=0 during t=0 and t=t1. Although I2(t) drops to zero during t=t1 to t=t2, V4(t) remains at a relatively constant positive voltage due to bypass capacitor 44. Because gate driver circuit 20 operates at a very high frequency, the ripples on V4(t) are negligible. A positive V4(t) causes IGBT 22 to be turned on. Typical values for V4(t) when an IGBT is used are in a range between about 10-15 V (e.g., 12V) and when a MOSFET is used in a range between about 8-12 V (e.g., 9V). The higher V4(t) becomes, the greater the current flowing through IGBT 22.

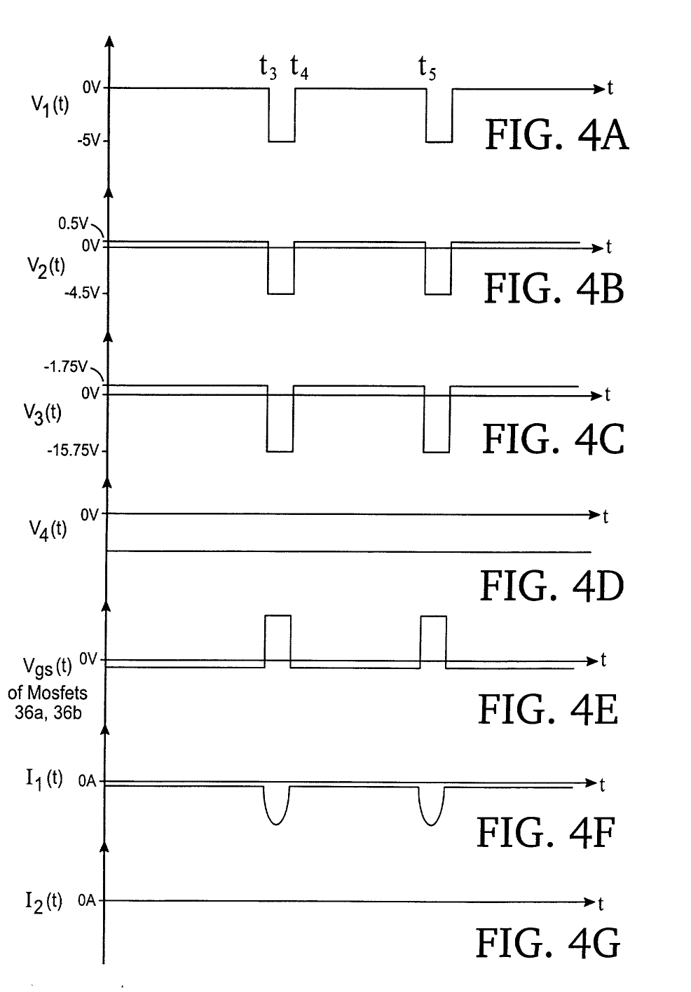

Referring to FIGS. 4A-4G, when IGBT 22 is desired to be turned off, control logic and oscillator circuit 25 generates signals to produce a negative pulse signal for V1(t). In this example, V1(t) is a negative pulse signal with a peak voltage of −5 volts and a period of 100 ns. The duty cycle of V1(t) is 10%, with a pulse width of 10 ns. Between time t=t3 and t=t4, V1(t) is maintained at −5 volts, V2(t) is maintained at −4.5 volts, and V3(t) is maintained at −15.75 volts. Vgs(t) is maintained at a positive voltage during t=t3 and t=t4. The exact value of this positive voltage is determined by the characteristics of the MOSFETs 36a and 36b. Because MOSFET 36b is a P-channel MOSFET, it is turned off when Vgs(t) is positive, and thus I2(t) becomes zero. Because MOSFET 36a is a N-channel MOSFET, it is turned on when Vgs(t) is positive, and thus I2(t) is positive during t=t3 to t=t4. Current I1(t) flows through resistor 35 to diode 38a and MOSFET 36a, creating a negative voltage drop V4(t) across the resistor.

Between time t=t4 and t=t5, V1(t) increases to zero, V2(t) increases to about 0.5 volts, and V3(t) increases to about 1.75 volts. Vgs(t) is maintained at a negative voltage that is above the Vgs threshold voltage of MOSFET 36b. Therefore, MOSFET 36b remains off, and I2(t)=0. A negative Vgs(t) turns off the N-channel MOSFET 36a, thus I1(t)=0 during t=t4 and t=t5. Although I1(t) drops to zero during t=t4 to t=t5, V4(t) remains at a relatively constant negative voltage due to bypass capacitor 44. Because gate driver circuit 20 operates at a very high frequency, the ripples on V4(t) are negligible. A negative V4(t) causes IGBT 22 to be turned off. Because gate driver circuit 20 operates at a high frequency, bypass capacitor 44 can discharge quickly, lowering V4(t) rapidly and thereby turning off IGBT 22 in a very short period.

Control logic and oscillator circuit 25, driver 24, FETs 26a and 26b all operate at logic potential, whereas output filter 35 and IGBT 22 operate at power potential. Because the difference between logic potential and power potential can range up to thousands of volts, it is important to provide isolation between that part of gate driver circuitry operating at logic potential and that part of gate driver circuitry operating at power potential. Unlike many conventional gate driver circuits, gate driver circuit 20 provides such isolation using only one component, namely transformer 32. Thus, other isolation devices including opto-coupler are no longer needed to provide isolation for the control signal path. The control signals pass through transformer 32, and transformer 32 itself provides the requisite isolation. Gate driver circuit 20 requires fewer components. Thus, the circuit is more reliable and is less expensive.

It is important to appreciate that gate driver 20 includes a single transmission path for both control signals and electric power signals. The PWM control signals generated by control logic and oscillator circuit 25 are sent to steering circuit 34 and output filter 35 via transformer 32. The duty cycle of the PWM signals generated at secondary windings 30b determines the voltage level at the base node of IGBT 22. In addition, the PWM signals also provide the electric power required for operating steering circuit 34. Because the PWM signals carry both control signals and power signals, the overall design of gate driver circuitry can be simplified. When the switching circuitry is operating at high frequencies, reduction of signal paths results in reduction of noise and interference. Thus, the overall performance is increased.

In the above embodiment, control logic and oscillator circuit 25 was used to supply control signals to one power transistor. It is important to appreciate that the concept of the invention is equally applicable to power supply systems having many power transistors or other high power output modules.

An embodiment of the invention has been described. Nevertheless, it will be understood that various modifications may be made without departing from the spirit and scope of the invention. Accordingly, other embodiments are within the scope of the following claims.

What is claimed is:

1. Circuitry for controlling a power semiconductor device, the circuitry comprising:
switching circuitry having an input for receiving a first control signal and an output for providing a second control signal to the power semiconductor device;
control logic circuitry adapted to provide the first control signal for controlling switching characteristics of and for supplying power to the switching circuitry; and
a signal transmission path configured to carry the first control signal from the control logic circuitry to the input of the switching circuitry and power for the switching circuitry.

2. The circuitry of claim 1, wherein the signal transmission path includes an isolation device electrically connected between the switching circuitry and the control logic circuitry.

3. The circuitry of claim 2, wherein the isolation device is a transformer.

4. The circuitry of claim 1, wherein the signal transmission path includes a DC blocking element between the control logic circuitry and the isolation device.

5. The circuitry of claim 1, wherein the control logic circuitry includes a driver circuit for driving an N-channel FET and a P-channel FET for generating the first control signal.

6. The circuitry of claim 1, wherein the switching circuitry is configured to receive an alternating current signal and generate a direct-current second control signal.

7. The circuitry of claim 1, wherein the switching circuitry is configured to provide synchronous rectification.

8. The circuitry of claim 1, wherein the first control signal is a pulse-width modulated (PWM) signal.

9. The circuitry of claim 8, wherein the switching circuitry is configured to increase the power flowing through the power semiconductor device by increasing the pulse width of the PWM signal.

10. The circuitry of claim 8, wherein the second control signal is a DC-modified signal that increases in response to an increase of pulse width of the PWM signal.

11. The circuitry of claim 1, wherein the power semiconductor device is an insulated gate bipolar transistor.

12. The circuitry of claim 1, wherein the switching circuitry is configured to operate in a frequency range between 10 KHz and 100 MHz.

13. The circuitry of claim 12, wherein the frequency is 10 MHz.

14. A method for controlling a power semiconductor device, the method comprising:
generating a first control signal using a control logic circuitry;
sending the first control signal to a switching circuitry via a signal transmission path that provides electric isolation between the control logic circuitry and the switching circuitry;
generating a second control signal from the first control signal using the switching circuitry;
supplying electric power from the first control signal in order to power the switching circuitry;
controlling the power semiconductor device using the second control signal.

15. The method of claim 14, wherein the control logic circuitry operates at logic potential, and the switching circuitry operates at power potential.

16. The method of claim 14 wherein the signal transmission path includes an isolation device electrically connected between the switching circuitry and the control logic circuitry.

17. The method of claim 16, wherein the isolation device is a transformer.

18. The method of claim 14, wherein the signal transmission path includes a DC blocking element between the control logic circuitry and the isolation device.

19. The method of claim 14, wherein the control logic circuitry includes a driver circuit for driving an N-channel FET and a P-channel FET for generating the first control signal.

20. The method of claim 14, wherein the switching circuitry is configured to receive an alternating current signal and generate a direct-current second control signal.

21. The method of claim 14, wherein the switching circuitry is configured to provide synchronous rectification.

22. The method of claim 14, wherein the first control signal is a pulse-width modulated (PWM) signal.

23. The method of claim 15, wherein the switching circuitry is configured to increase the power flowing through the power semiconductor device by increasing the pulse width of the PWM signal.

24. The method of claim 15, wherein the second control signal is a DC-modified signal that increases in response to an increase of pulse width of the PWM signal.

24. The method of claim 14, wherein the power semiconductor device is an insulated gate bipolar transistor.

25. The method of claim 14, wherein the switching circuitry is configured to operate in a frequency range between 10 KHz and 100 MHz.

26. The method of claim 25, wherein the frequency is 10 MHz.
